(19) United States
(12) Patent Application Publication
(10) Pub. No.: US 2010/0244118 A1
(43) Pub. Date: Sep. 30, 2010

(54) Nonvolatile Memory Device and Method of Manufacturing the Same

(75) Inventor: Kyeong Bock Lee, Icheon-si (KR)

Correspondence Address: MARSHALL, GERSTEIN & BORUN LLP, 233 SOUTH WACKER DRIVE, 6300 WILLIS TOWER, CHICAGO, IL, 60606-6357, US

(73) Assignee: HYNIX SEMICONDUCTOR INC., Icheon-si (KR)

(21) Appl. No.: 12/650,487

(22) Filed: Dec. 30, 2009

(30) Foreign Application Priority Data
Mar. 24, 2009 (KR) 10-2009-0024936

(51) Int. Cl. H01L 29/788; H01L 21/28

(52) U.S. Cl. 257/319; 438/587; 257/E29.3; 257/E21.179

(57) ABSTRACT

A nonvolatile memory device comprises floating gates formed over an active region of a semiconductor substrate, isolation layers formed within respective isolation regions of the semiconductor substrate, first nitridation patterns formed on sidewalls of the floating gates, a first insulating layer, a second nitride layer, a second insulating layer, and a third nitride layer formed on an entire surface of the first nitridation patterns and the isolation layers, and control gates formed over the third nitride layer.

### CROSS-REFERENCE TO RELATED APPLICATION

Priority to Korean patent application number 10-2009-0024936 filed on Mar. 24, 2009, the entire disclosure of which is incorporated by reference herein, is claimed.

### BACKGROUND

One or more embodiments relate generally to a nonvolatile memory device and to a method of manufacturing the same and, more particularly, to a nonvolatile memory device and a method of manufacturing the same, which are capable of improving the electrical properties of a dielectric layer.

A nonvolatile memory device includes a gate insulating layer for the tunneling of electrons, floating gates for storing data, a dielectric layer for coupling, and control gates for transferring driving voltages.

FIG. 1 is a photograph illustrating the problems of a known nonvolatile memory device.

Referring to FIG. 1, isolation layers 12 are formed in a semiconductor substrate 10, and a gate insulating layer 14 and floating gates 16 are formed over the active region of the semiconductor substrate 10. A dielectric layer is formed on the entire surface of the isolation layers 12 and the floating gates 16. The dielectric layer typically has been formed to have a stacked ONO structure of an oxide layer, a nitride layer, and an oxide layer. To improve the capacitance of the dielectric layer, a nitride layer may be formed before the dielectric layer is formed. In more detail, a first nitride layer 18, a first insulating layer 20, a second nitride layer 22, and a second insulating layer 24 are often formed to constitute the dielectric layer. A third nitride layer 26 is often further formed over the second insulating layer 24. In the case in which the number of nitride layers is increased as described above, capacitance is increased. Accordingly, the speed of a program operation can be enhanced, and a distribution characteristic of threshold voltages can also be improved.

However, electrons trapped at a nitride layer cannot move to neighboring memory cells because of an electron (e) trap characteristic of the nitride layer. In other words, electrons trapped at the first nitride layer 18 neighboring the floating gate 16 can move through the first nitride layer 18 formed over the isolation layer 12. Accordingly, the retention characteristic of the nonvolatile memory device can deteriorate.

### BRIEF SUMMARY

According to one or more embodiments, a first nitride layer for a dielectric layer is formed on the entire surface of floating gates and isolation layers. The first nitride layer formed over the isolation layers is removed, but the first nitride layer formed on the sidewalls of the floating gates remains intact. Accordingly, a phenomenon in which electrons move to neighboring memory cells can be prevented.

A nonvolatile memory device according to an aspect of the present disclosure comprises floating gates formed over an active region of a semiconductor substrate, isolation layers formed within respective isolation regions of the semiconductor substrate, first nitridation patterns formed on sidewalls of the floating gates, a first insulating layer, a second nitride layer, a second insulating layer, and a third nitride layer formed on an entire surface of the first nitridation patterns and the isolation layers, and control gates formed over the third nitride layer.

The first and second insulating layers preferably each comprise an oxide layer. An additional insulating layer preferably is formed between the first insulating layer and an upper side of each of the floating gates. The additional insulating layer preferably comprises an oxide layer.

The first nitridation patterns preferably are isolated from each other on the upper side of each of the isolation layers.

A method of manufacturing a nonvolatile memory device according to another aspect of the present disclosure comprises providing a semiconductor substrate, forming first conductive patterns over an active region and isolation layers within respective isolation regions of the semiconductor substrate, forming a first nitride layer on an entire surface of the isolation layers and the first conductive patterns, performing an etch process to isolate portions of the first nitride layer on an upper side of each of the isolation layers and on an upper side of each of the first conductive patterns from each other, thereby forming first nitridation patterns, forming a first insulating layer, a second nitride layer, and a second insulating layer on an entire surface of the first nitridation patterns, the first conductive patterns, and the isolation layers, and forming a second conductive layer over the second insulating layer.

Before forming the second conductive layer, a third nitride layer preferably is formed over the second insulating layer.

The first nitride layer preferably is formed by a plasma nitridation process. The etch process preferably is a dry etch process, highly preferably an anisotropic dry etch process.

The first nitridation patterns preferably are formed on sidewalls of the first conductive patterns. The first nitridation patterns preferably are formed over the first conductive patterns and the isolation layers, but are isolated from each other in a portion of the upper side of each of the isolation layers.

After forming the first nitridation patterns, an additional insulating layer preferably is formed on the upper side of each of the exposed first conductive patterns.

The additional insulating layer preferably comprises an oxide layer. The additional insulating layer preferably is formed using an oxide growth method. The first and second insulating layers preferably each comprise an oxide layer.

The third nitride layer preferably is formed by a plasma nitridation process.

### BRIEF DESCRIPTION OF THE DRAWINGS

FIG. 1 is a photograph illustrating the problems of a known nonvolatile memory device;

FIGS. 2A to 2H are cross-sectional views illustrating a nonvolatile memory device and a method of manufacturing the same according to an embodiment of the present disclosure; and

FIGS. 3A to 3G are cross-sectional views illustrating a nonvolatile memory device and a method of manufacturing the same according to another embodiment of the present disclosure.

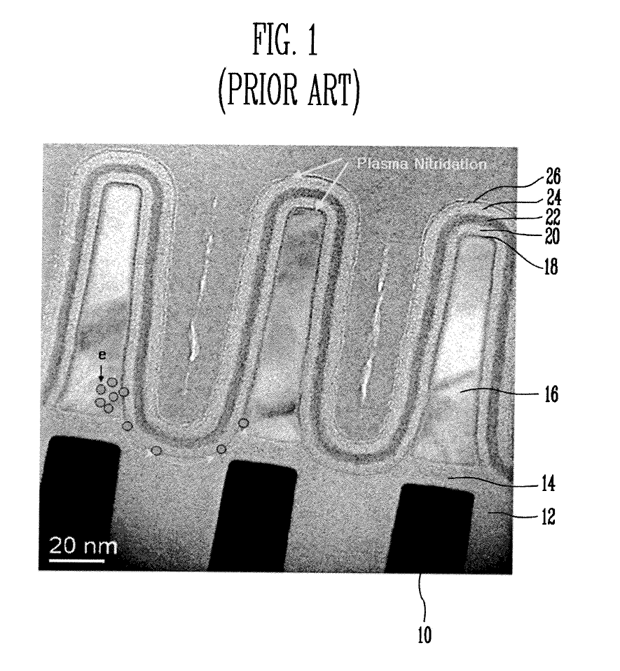

### DESCRIPTION OF EMBODIMENTS

Various embodiments of the present disclosure are described in detail below with reference to the accompanying drawings. The drawing figures are provided to allow those having ordinary skill in the art to understand the scope of the embodiments of the disclosure.

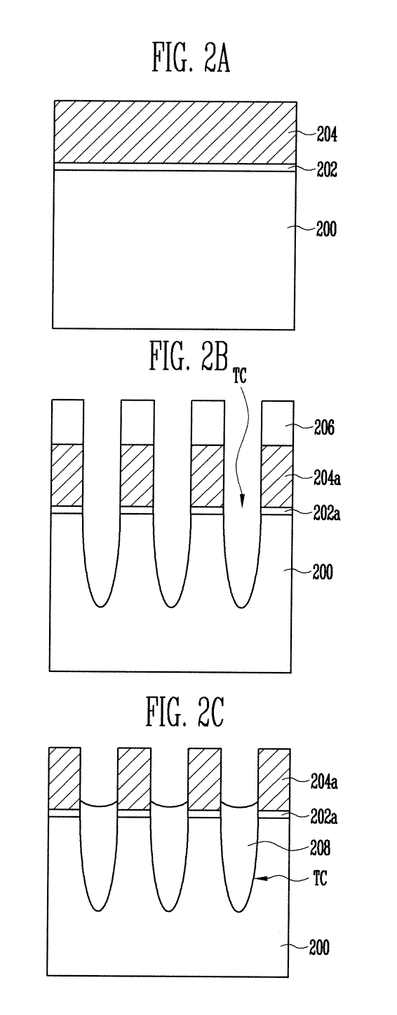

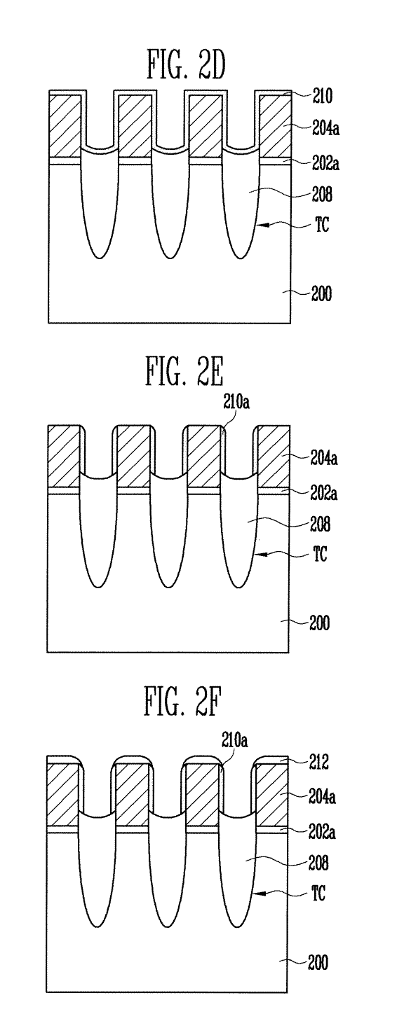

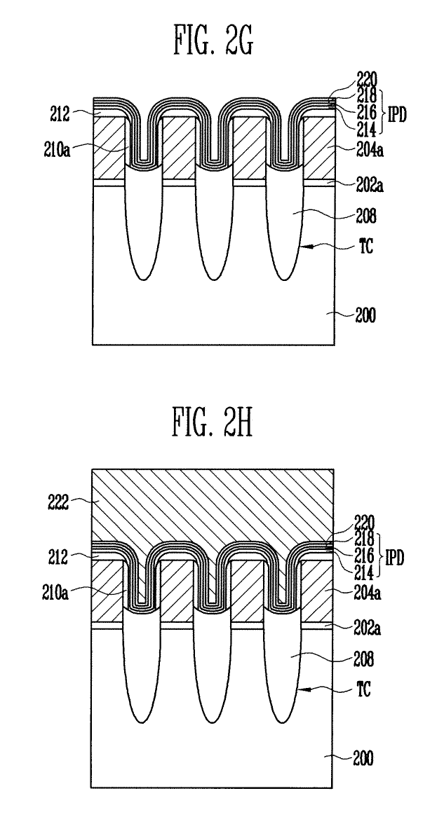

FIGS. 2A to 2H are cross-sectional views illustrating a nonvolatile memory device and a method of manufacturing the same according to an embodiment of the present disclosure.

Referring to FIG. 2A, a gate insulating layer 202 for the tunneling of electrons and a first conductive layer 204 for floating gates are formed over a semiconductor substrate 200. The gate insulating layer 202 preferably comprises an oxide layer. The first conductive layer 204 preferably comprises a polysilicon layer. The polysilicon layer for floating gates preferably is formed by stacking an undoped polysilicon layer and a doped polysilicon layer.

Referring to FIG. 2B, an isolation mask pattern 206 for forming isolation regions is formed over the first conductive layer 204. The isolation mask pattern 206 preferably comprises a nitride layer. The first conductive layer 204 and the gate insulating layer 202 are patterned using the isolation mask pattern 206 to form first conductive patterns 204a and gate insulating patterns 202a. Next, a portion of the exposed semiconductor substrate 200 is etched to form trenches TC, which become isolation regions.

After forming the trenches TC, a liner insulating layer (not shown) may be further formed in order to compensate for etch damage to the semiconductor substrate 200 resulting from the etch process.

Referring to FIG. 2C, after forming isolation layers 208 within the respective trenches TC, the isolation mask pattern 206 is removed. The height of the isolation layers 208 is lowered by performing an etch process to control the effective field height (EFH). Here, the height of the isolation layers 208 is controlled such that the gate insulating patterns 202a are not exposed.

Referring to FIG. 2D, a first nitride layer 210 for a dielectric layer is formed on the entire surface of the isolation layers 208 and the first conductive patterns 204a. In the case in which a nitride layer is formed as described above, capacitance can be improved when a program operation for a nonvolatile memory device is performed.

The first nitride layer 210 preferably comprises a nitride layer and highly preferably is formed by a plasma nitridation process. The first nitride layer 210 preferably has a thickness less than 30 Å, highly preferably 5 Å to 30 Å.

Referring to FIG. 2E, to prevent electrons from moving to neighboring memory cells, an etch process for removing a portion of the first nitride layer 210 formed on the upper sides of the isolation layers 208 is performed, thereby forming first nitridation patterns 210a. Thus, the first nitridation patterns 210a block a path along which electrons are moved, and the nitridation patterns 210a may partially remain on the upper sides of the isolation layers 208. In particular, the first nitridation patterns 210a remain on the sidewalls of the first conductive patterns 204a such that a reduction in the capacitance when a program operation is performed can be suppressed to the maximum extent.

The etch process for forming the first nitridation patterns 210a preferably is performed using a dry etch process, highly preferably an anisotropic dry etch process. When the first nitride layer 210 formed on the upper sides of the isolation layers 208 is removed, a portion of the first nitride layer 210 formed on the upper sides of the first conductive patterns 204a can also be removed. Accordingly, the first nitridation patterns 210a primarily remain on the sidewalls of the first conductive patterns 204a. Here, the amount of the first nitridation patterns 210a remaining on the sidewalls of the first conductive patterns 204a is much greater than that of the first nitride layer 210 removed from the upper sides of the first conductive patterns 204a. Accordingly, a reduction in the capacitance can be suppressed to the maximum extent.

Referring to FIG. 2F, in the case in which the upper sides of the first conductive patterns 204a are exposed in the etch process for forming the first nitridation patterns 210a, an additional insulating layer 212 can be further formed in order to compensate for etch damage to the upper sides of the first conductive patterns 204a. The additional insulating layer 212 preferably comprises an oxide layer and highly preferably is formed using an oxide growth method to selectively form the additional insulating layer 212 on the upper sides of the exposed first conductive patterns 204a.

Referring to FIG. 2G, a first insulating layer 214, a second nitride layer 216, and a second insulating layer 218 are formed over the entire surface of the additional insulating layer 212, the first nitridation patterns 210a, and the isolation layers 208. Accordingly, a dielectric layer IPD having a stack structure of the first insulating layer 214, the second nitride layer 216, and the second insulating layer 218, including the additional insulating layer 212, is formed over the first conductive patterns 204a. The first nitridation patterns 210a, together with the dielectric layer IPD, are formed on the sidewalls of the first conductive patterns 204a, and therefore are capable of improving capacitance when a program operation is performed.

Furthermore, to further enhance capacitance, a third nitride layer 220 preferably is formed on a surface of the second insulating layer 218. The third nitride layer 220 may be included in the dielectric layer IPD, if desired. Accordingly, the dielectric layer IPD preferably has an oxide-nitride-oxide-nitride (ONON) structure on the upper sides of the first conductive patterns 204a and a nitride-oxide-nitride-oxide-nitride (NONON) structure on the sidewalls of the first conductive patterns 204a. The third nitride layer 220 preferably comprises a nitride layer and highly preferably is formed by a plasma nitridation process. The third nitride layer 220 preferably has a thickness less than 30 Å, highly preferably 5 Å to 30 Å.

Referring to FIG. 2H, a second conductive layer 222 for control gates preferably is formed over the third nitride layer 220. Alternatively, in the case in which the third nitride layer 220 is not formed, the second conductive layer 222 is formed over the second insulating layer 218.

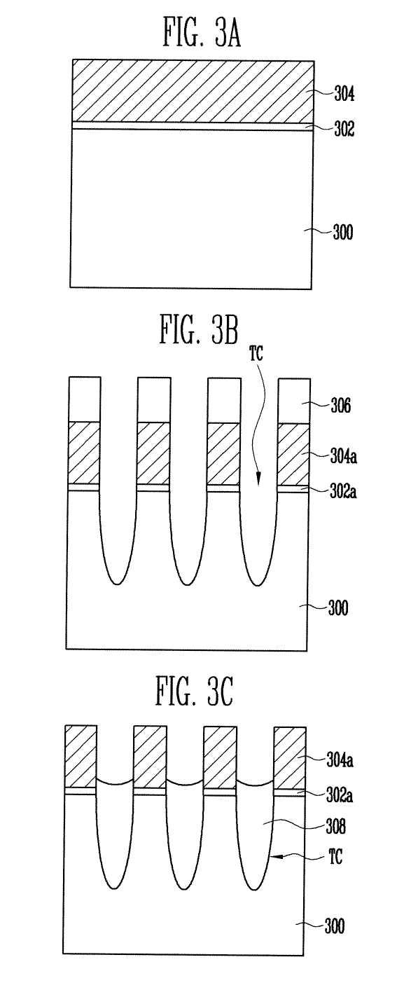

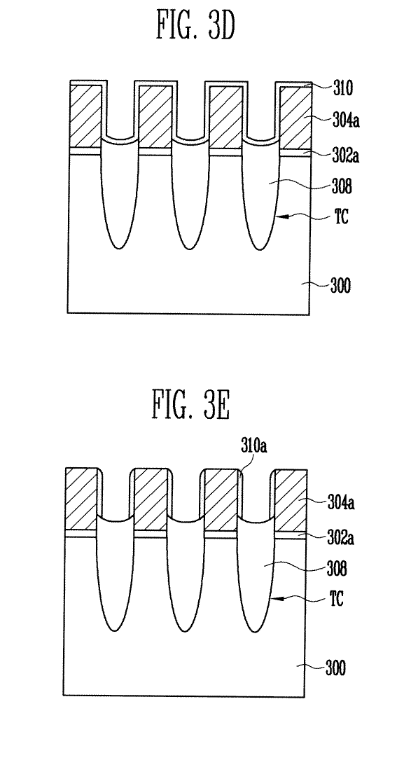

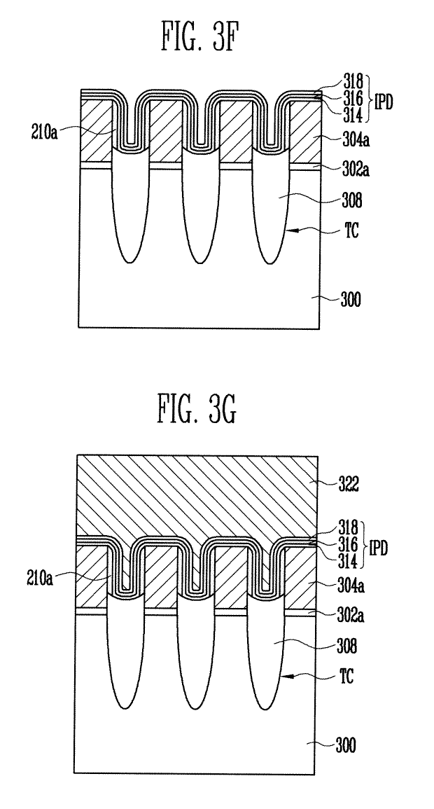

FIGS. 3A to 3G are cross-sectional views illustrating a nonvolatile memory device and a method of manufacturing the same according to another embodiment of the present disclosure.

Referring to FIG. 3A, a gate insulating layer 302 for the tunneling of electrons and a first conductive layer 304 for floating gates are formed over a semiconductor substrate 300. The gate insulating layer 302 preferably comprises an oxide layer. The first conductive layer 304 preferably comprises a polysilicon layer. The polysilicon layer for floating gates preferably is formed by stacking an undoped polysilicon layer and a doped polysilicon layer.

Referring to FIG. 3B, an isolation mask pattern 306 for forming isolation regions is formed over the first conductive layer 304. The isolation mask pattern 306 preferably comprises a nitride layer. The first conductive layer 304 and the gate insulating layer 302 are patterned using the isolation mask pattern 306 to form first conductive patterns 304a and gate insulating patterns 302a. Next, a portion of the exposed semiconductor substrate 300 is etched to form trenches TC, which become isolation regions.

After forming the trenches TC, a liner insulating layer (not shown) preferably is formed to compensate for etch damage to the semiconductor substrate 300 resulting from the etch process.

Referring to FIG. 3C, after forming isolation layers 308 within the respective trenches TC, the isolation mask pattern 306 is removed. The height of the isolation layers 308 is lowered by performing an etch process to control the effective field height (EFH). Here, the height of the isolation layers 308 is controlled such that the gate insulating patterns 302a are not exposed.

Referring to FIG. 3D, a first nitride layer 310 for a dielectric layer is formed on the entire surface of the isolation layers 308 and the first conductive patterns 304a. In the case in which a nitride layer is formed as described above, capacitance can be improved when a program operation for a nonvolatile memory device is performed.

The first nitride layer 310 preferably comprises a nitride layer and highly preferably is formed by a plasma nitridation process. The first nitride layer 310 preferably has a thickness less than 30 Å, highly preferably 5 Å to 30 Å.

Referring to FIG. 3E, to prevent electrons from moving to neighboring memory cells, an etch process for removing a portion of the first nitride layer 310 formed on the upper sides of the isolation layers 308 is performed, thereby forming first nitridation patterns 310a. Thus, the first nitridation patterns 310a block a path along which electrons are moved, and the nitridation pattern may partially remain on the upper sides of the isolation layers 308. In particular, the first nitridation patterns 310a remain on the sidewalls of the first conductive patterns 304a such that a reduction in the capacitance when a program operation is performed can be suppressed to the maximum extent.

The etch process for forming the first nitridation patterns 310a preferably performed using a dry etch process, highly preferably an anisotropic dry etch process. When the first nitride layer 310 formed on the upper sides of the isolation layers 308 is removed, a portion of the first nitride layer 310 formed on the upper sides of the first conductive patterns 304a can also be removed. Accordingly, the first nitridation patterns 310a primarily remain on the sidewalls of the first conductive patterns 304a. Here, the amount of the first nitridation patterns 310a remaining on the sidewalls of the first conductive patterns 304a is much greater than that of the first nitride layer 310 removed from the upper sides of the first conductive patterns 304a. Accordingly, a reduction in the capacitance can be suppressed to the maximum extent.

Referring to FIG. 3F, a first insulating layer 314, a second nitride layer 316, and a second insulating layer 318 are formed on the entire surface of the first nitridation patterns 310a and the isolation layers 308. Accordingly, a dielectric layer IPD having an oxide-nitride-oxide (ONO) stack structure of the first insulating layer 314, the second nitride layer 316, and the second insulating layer 318 is formed over the first conductive patterns 304a. Further, the dielectric layer IPD having a nitride-oxide-nitride-oxide (NONO) structure is formed on the sidewalls of the first conductive patterns 304a. Accordingly, capacitance when a program operation is performed can be improved.

Referring to FIG. 3G, a second conductive layer 322 for control gates is formed over the second nitride layer 318.

As described above, a nitride layer is further formed at the bottom of the dielectric layer, and a portion of the nitride layer formed between the floating gates is isolated from each other, and therefore is capable of preventing electrons from moving. Accordingly, capacitance can be improved, and deterioration in the retention characteristic of a nonvolatile device can be prevented.

According to the present disclosure, the first nitride layer for the dielectric layer is formed on the entire surface of the floating gates and the isolation layers. The first nitride layer formed over the isolation layers is removed, and the first nitride layer formed on the sidewalls of the floating gates remains intact. Accordingly, a phenomenon in which electrons move to neighboring memory cells can be prevented. Consequently, a reduction in the capacitance of the dielectric layer can be suppressed, and deterioration in the retention characteristic of a nonvolatile memory device can be prevented.

What is claimed is:

1. A nonvolatile memory device, comprising:
floating gates formed over an active region of a semiconductor substrate;
isolation layers formed within respective isolation regions of the semiconductor substrate;
first nitridation patterns formed on the sidewalls of the floating gates;
a first insulating layer, a second nitride layer, a second insulating layer, and a third nitride layer formed on an entire surface of the first nitridation patterns and the isolation layers; and
control gates formed over the third nitride layer.

2. The nonvolatile memory device of claim 1, wherein the first and second insulating layers each comprise an oxide layer.

3. The nonvolatile memory device of claim 1, further comprising an additional insulating layer formed between the first insulating layer and an upper side of each of the floating gates.

4. The nonvolatile memory device of claim 3, wherein the additional insulating layer comprises an oxide layer.

5. The nonvolatile memory device of claim 1, wherein the first nitridation patterns are isolated from each other on an upper side of each of the isolation layers.

6. A method of manufacturing a nonvolatile memory device, the method comprising:
providing a semiconductor substrate;
forming first conductive patterns over an active region of the semiconductor substrate and forming isolation layers within respective isolation regions of the semiconductor substrate;
forming a first nitride layer on an entire surface of the isolation layers and the first conductive patterns;
performing an etch process to isolate portions of the first nitride layer on an upper side of each of the isolation layers and on an upper side of each of the first conductive patterns from each other, thereby forming first nitridation patterns;
forming a first insulating layer, a second nitride layer, and a second insulating layer on an entire surface of the first nitridation patterns, the first conductive patterns, and the isolation layers; and
forming a second conductive layer over the second insulating layer.

7. The method of claim 6, further comprising, before forming the second conductive layer, forming a third nitride layer over the second insulating layer.

8. The method of claim 6, comprising forming the first nitride layer by a plasma nitridation process.

9. The method of claim 6, wherein the etch process is a dry etch process.

10. The method of claim 9, wherein the etch process is an anisotropic dry etch process.

11. The method of claim 6, comprising forming the first nitridation patterns on sidewalls of the first conductive patterns.

12. The method of claim 6, comprising forming the first nitridation patterns over the first conductive patterns and the isolation layers so that the first nitridation patterns are isolated from each other in a portion of the upper side of each of the isolation layers.

13. The method of claim 6, further comprising, after forming the first nitridation patterns, forming an additional insulating layer on an upper side of each of the exposed first conductive patterns.

14. The method of claim 13, wherein the additional insulating layer comprises an oxide layer.

15. The method of claim 13, comprising forming the additional insulating layer using an oxide growth method.

16. The method of claim 6, wherein the first and second insulating layers each comprise an oxide layer.

17. The method of claim 7, comprising forming the third nitride layer by a plasma nitridation process.
